(19) United States
(12) Patent Application Publication
(10) Pub. No.: US 2025/0210324 A1
(43) Pub. Date: Jun. 26, 2025

(54) WAFER PLACEMENT TABLE

(71) Applicant: NGK INSULATORS, LTD., Nagoya-City (JP)

(72) Inventors: Tomohiro HARA, Handa-City (JP); Hiroshi TAKEBAYASHI, Handa-City (JP)

(73) Assignee: NGK INSULATORS, LTD., Nagoya-City (JP)

(21) Appl. No.: 18/999,047

(22) Filed: Dec. 23, 2024

Related U.S. Application Data
(63) Continuation of application No. PCT/JP2023/046069, filed on Dec. 22, 2023.

(51) Int. Cl. H01J 37/32

(52) U.S. Cl. CPC H01J 37/32715; H01J 37/32541; H01J 37/32568; H01J 37/32577; H01J 2237/032

(57) ABSTRACT

A wafer placement table includes: a first conductive layer; a second conductive layer different in height from the first conductive layer; and a connector that electrically connect the first conductive layer and the second conductive layer, inside a ceramic plate having a wafer placement surface on its upper surface. The first conductive layer, the second conductive layer and the connector are formed in a seamless one-piece structure.

### BACKGROUND OF THE INVENTION

### 1. Field of the Invention

The present invention relates to a wafer placement table.

### 2. Description of the Related Art

A known conventional wafer placement table includes the following components inside a ceramic plate: a disk-shaped main RF electrode; an annular sub-RF electrode provided on the outer circumferential side of the main RF electrode; a rectangular planar jumper provided below the sub-RF electrode; and a connector that electrically connects the sub-RF electrode and the jumper. For example, PTL 1 discloses such a wafer placement table in which a horizontally placed coil is utilized as the connector.

### CITATION LIST

### Patent Literature

PTL 1: JP 2023-087447 A

### SUMMARY OF THE INVENTION

However, since a coil is utilized as the connector in PTL 1, a portion of the sub-RF electrode and the jumper may be deformed by the coil, the portion being in contact with the coil, and the contact resistance between the sub-RF electrode and the coil, and the contact resistance between the jumper and the coil may vary with the wafer placement table. Therefore, it may be difficult to stably ensure the electrical connection between the sub-RF electrode, the connector and the jumper layer.

The present invention has been devised to solve the above-mentioned problem, and it is a main object to stably ensure the electrical connection between two conductive layers with different heights.
[1] A wafer placement table of the present invention includes: a first conductive layer; a second conductive layer different in height from the first conductive layer; and a connector that electrically connect the first conductive layer and the second conductive layer, inside a ceramic plate having a wafer placement surface on its upper surface. The first conductive layer, the second conductive layer and the connector are formed in a seamless one-piece structure.

In the wafer placement table, the first conductive layer, the second conductive layer and the connector are formed in a seamless one-piece structure. Thus, the first conductive layer and the connector cannot be disconnected as well as the second conductive layer and the connector cannot be disconnected. Therefore, it is possible to stably ensure the electrical connection between the first and second conductive layers with different heights.

In the present description, “upper”, “lower” do not represent absolute positional relationship, but represent relative positional relationship. Thus, depending on the orientation of the wafer placement table, “upper” and “lower” may indicate “lower” and “upper”, “left” and “right”, or “front” and “back”. The “seamless one-piece structure” is the structure obtained, for example, by cutting out the first conductive layer, the second conductive layer and the connector in a contiguous state from one sheet of conductive material, and folding the cut-out material.
[2] The wafer placement table of the present invention (the wafer placement table according to [1]) may include: a main RF electrode provided inside the ceramic plate; a sub-RF electrode as the first conductive layer provided on an outer circumferential side of the main RF electrode; a jumper as the second conductive layer provided below the sub-RF electrode; a main RF electrode rod electrically connected to the main RF electrode; and a sub-RF electrode rod electrically connected to the jumper. In the wafer placement table, the sub-RF electrode, the jumper and the connector are formed in a seamless one-piece structure. Thus, the sub-RF electrode and the connector cannot be disconnected as well as the jumper and the connector cannot be disconnected. Therefore, it is possible to stably ensure the electrical connection between the sub-RF electrode and the jumper.
[3] In the wafer placement table of the present invention (the wafer placement table according to [2]), the jumper may include a horizontal conductor provided at a central portion of the ceramic plate; and a plurality of first conductive wires that horizontally extend from an outer edge of the conductor and have rotational symmetry, the connector may be formed by a plurality of second conductive wires that respectively extend diagonally upward from the plurality of first conductive wires, and the sub-RF electrode may be a ring-shaped set in which horizontal conductive arc portions respectively contiguous to the plurality of second conductive wires are arranged in a circumferential direction. In this manner, even when the one-piece structure is produced from a relatively hard conductive material, the one-piece structure can be produced relatively easily. Because the plurality of second conductive wires included in the connector have rotational symmetry, occurrence of variation in the plasma density can be prevented.

Note that “horizontal” indicates not only completely horizontal, but also horizontal in an acceptable range (for example, with a tolerance) (the same applies to the following).
[4] In the wafer placement table of the present invention (the wafer placement table according to [2]), the jumper may be a horizontal conductor provided at a central portion of the ceramic plate, the connector may be formed by a plurality of conductive wires that extend diagonally upward from an outer edge of the conductor and have rotational symmetry, and the sub-RF electrode may be a ring-shaped set in which horizontal conductive arc portions respectively contiguous to the plurality of conductive wires are arranged in a circumferential direction. Also, in this setting, even when the one-piece structure is produced from a relatively hard conductive material, the one-piece structure can be produced relatively easily. Because the plurality of conductive wires included in the connector have rotational symmetry, occurrence of variation in the plasma density can be prevented.
[5] In the wafer placement table of the present invention (the wafer placement table according to any one of [2] to [4]), a boundary between the jumper and the connector may be located inside the main RF electrode in a plan view. In this manner, the angle of inclination of the connector can be reduced.
[6] In the wafer placement table of the present invention (the wafer placement table according to any one of [2 ]to [5]), a boundary between the jumper and the connector may be a valley fold line in a plan view, and a boundary between the sub-RF electrode and the connector may be a mountain fold line in a plan view. In this manner, the one-piece structure can be manufactured relatively easily.
[7] In the wafer placement table of the present invention (the wafer placement table according to any one of [2] to [5]), a boundary between the jumper and the connector may be a valley fold line in a plan view, and a boundary between the sub-RF electrode and the connector may be a valley fold line in a plan view. In this manner, the angle of inclination of the connector can be reduced.
[8] The wafer placement table of the present invention (the wafer placement table according to any one of [2] to [7]) may include a tubular shaft connected to a lower surface of the ceramic plate, and the main RF electrode rod and the sub-RF electrode rod may be disposed in an internal space of the tubular shaft. In the wafer placement table including the tubular shaft, the sub-RF electrode rod needs to be disposed in the internal space of the tubular shaft, thus application of the present invention has a high significance.
[9] In the wafer placement table of the present invention (the wafer placement table according to any one of [1] to [8]), the one-piece structure may be made of a conductive mesh. In this manner, when the ceramic plate is manufactured, the ceramic powder is likely to pass through the one-piece structure in a vertical direction, thus the ceramic powder is likely to be distributed over the entirety thereof.
[10] In the wafer placement table of the present invention (the wafer placement table according to [3] or [4]), the conductor of the jumper may have a vertical through-hole. In this manner, the area of the jumper is smaller than in the case where the jumper has no hole.

### BRIEF DESCRIPTION OF THE DRAWINGS

FIG. 1 is a vertical cross-sectional view of wafer placement table 10 installed in chamber 52.

FIG. 2 is a plan view of the wafer placement table 10.

FIGS. 3A and 3B are explanatory views of one-piece structure 30.

FIG. 4 is an explanatory view of one-piece structure precursor 32.

FIGS. 5A to 5F illustrate manufacturing process charts for the wafer placement table 10.

FIG. 6 is a vertical cross-sectional view of wafer placement table 110.

FIG. 7 is a plan view of the wafer placement table 110.

FIGS. 8A and 8B are explanatory views of one-piece structure 80.

FIG. 9 is an explanatory view of one-piece structure precursor 82.

FIG. 10 is a vertical cross-sectional view of a wafer placement table including resistance heating element 90.

FIG. 11 is a vertical cross-sectional view of a wafer placement table including resistance heating element 90.

### DETAILED DESCRIPTION OF THE INVENTION

### First Embodiment

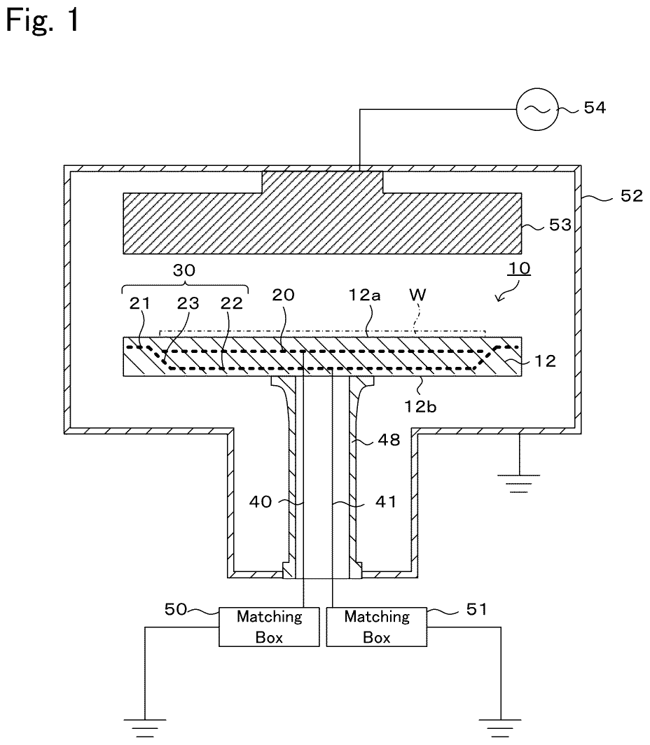

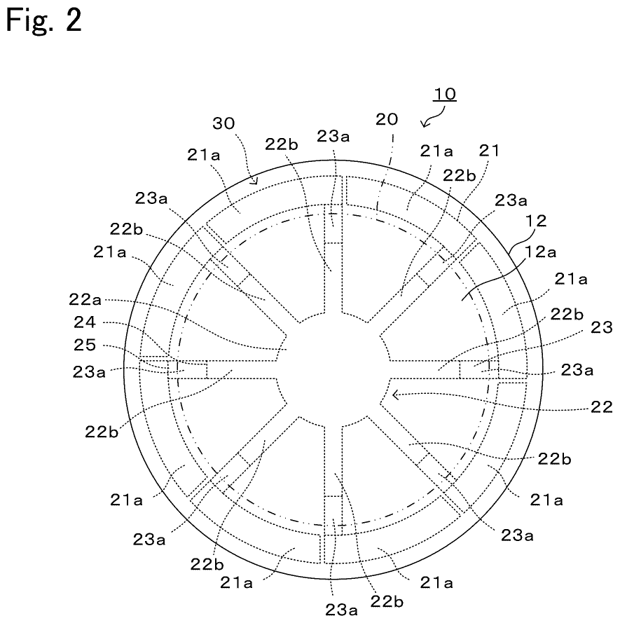

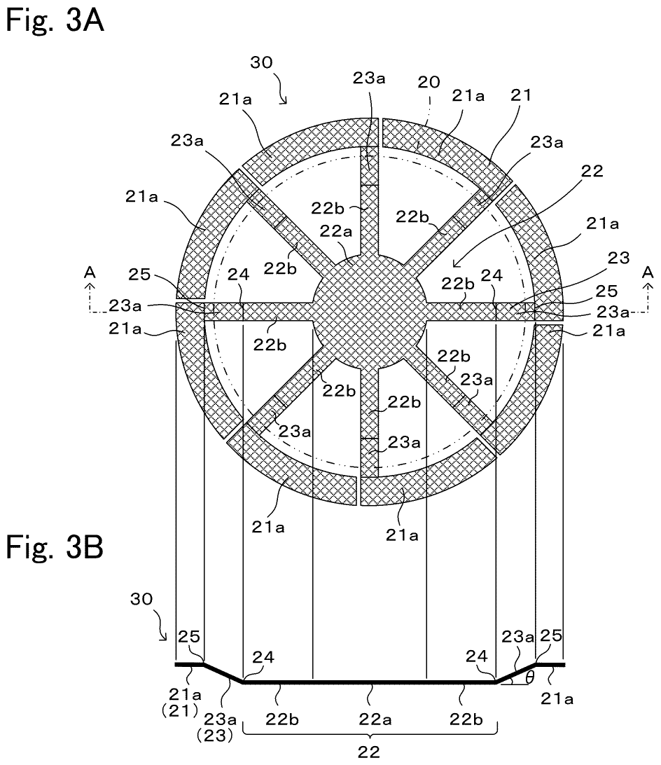

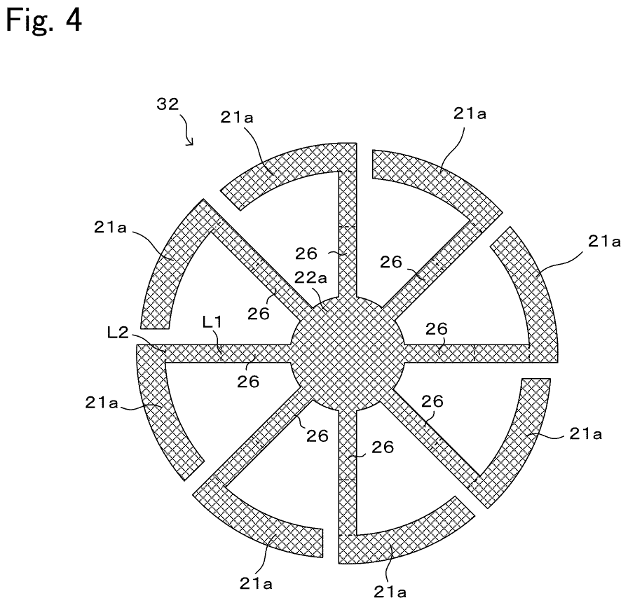

A preferred embodiment of the present invention will be described below with reference to the drawings. FIG. 1 is a vertical cross-sectional view of wafer placement table 10 installed in chamber 52, FIG. 2 is a plan view of the wafer placement table 10, FIGS. 3A and 3B show explanatory views of one-piece structure 30 (FIG. 3A is a plan view, FIG. 3B is an A-A cross-sectional view), and FIG. 4 is a plan view of one-piece structure precursor 32.

The wafer placement table 10 is used in a semiconductor manufacturing device, particularly, in a semiconductor manufacturing device that processes wafer W with plasma, and as illustrated in FIG. 1, the wafer placement table 10 is installed inside a chamber 52 for a semiconductor process. The wafer placement table 10 includes a ceramic plate 12, and a tubular shaft 48 joined to a lower surface 12b of the ceramic plate 12. A main RF electrode 20 and a one-piece structure 30 (a sub-RF electrode 21, a jumper 22 and a connector 23) are embedded in the ceramic plate 12.

The ceramic plate 12 is a disk-shaped plate made of a ceramic material represented by aluminum nitride, silicon carbide, silicon nitride, or aluminum oxide. The ceramic plate 12 has a circular wafer placement surface 12a on its upper surface. A plurality of irregularities (not illustrated) are formed on the wafer placement surface 12a by embossing. A gas (e.g., He gas) for heat transfer is designed to be supplied from the lower surface 12b of the ceramic plate 12 to the space between recessed portions provided in the wafer placement surface 12a and the wafer W placed on the wafer placement surface 12a through a gas supply path which is not illustrated. The diameter of the ceramic plate 12 is e.g., 320 to 380 mm.

The main RF electrode 20 is a disk electrode concentric with the ceramic plate 12, and is provided to be opposed to the wafer placement surface 12a and parallel to the wafer placement surface 12a. The “parallel” indicates completely parallel as well as parallel in a range (e.g., with a tolerance) of acceptable error (the same applies to the following). The main RF electrode 20 is an electrode containing, as the main component, Mo, Nb, W, Ta, carbide of any of these, or a high melting point composite metal containing two or more of these. The main RF electrode is made of metal mesh or punching metal, but is preferably made of metal mesh. The wire diameter of the metal mesh is preferably 0.1 mm or more (e.g., 0.1 to 2 mm). The main component refers to one of components, which has the highest content rate (the same applies to the following). The main RF electrode 20 is designed so that when a plasma is generated in the space above a central area of the wafer W placed on the wafer placement surface 12a, a RF voltage is applied across an upper electrode (a shower head 53 described below) and the main RF electrode 20. The main RF electrode 20 is electrically connected to a main RF electrode rod 40 which is inserted in the lower surface 12b of the ceramic plate 12. The main RF electrode rod 40 is disposed so as not to be in contact with the jumper 22. The diameter of the main RF electrode 20 is e.g., around 300 mm.

The sub-RF electrode 21, the jumper 22 and the connector 23 are formed in the seamless one-piece structure 30.

As illustrated in FIG. 1, the sub-RF electrode 21 is embedded inside the ceramic plate 12 and above the main RF electrode 20. The sub-RF electrode 21 is disposed on the outer circumferential side of the main RF electrode 20. As illustrated in FIG. 2, FIGS. 3A and 3B, the sub-RF electrode 21 is a ring-shaped set in which a plurality of horizontal conductive arc portions 21a are arranged in a circumferential direction. Adjacent conductive arc portions 21a of the sub-RF electrode 21 are disposed with a slight gap. However, adjacent conductive arc portions 21a may be disposed so as to overlap with each other. As illustrated in FIG. 2, the inner diameter of the ring-shaped sub-RF electrode 21 is greater than the outer diameter of the main RF electrode 20, and the outer diameter of the ring-shaped sub-RF electrode 21 is less than the diameter of the ceramic plate 12. The width of the sub-RF electrode 21 is preferably 5 to 40 mm.

As illustrated in FIG. 1, the jumper 22 is embedded inside the ceramic plate 12 and below the main RF electrode 20 and the sub-RF electrode 21. The jumper 22 is electrically connected to the sub-RF electrode rod 41 which is inserted in the lower surface 12b of the ceramic plate 12. The distance between the jumper 22 and the sub-RF electrode 21 in the height direction is preferably 2 to 20 mm. As illustrated in FIG. 2, FIGS. 3A and 3B, the jumper 22 includes: a horizontal circular conductor 22a provided at a central portion of the ceramic plate 12 (FIG. 2); and a plurality of first conductive wires 22b that horizontally extend from the circular conductor 22a and have rotational symmetry. The circular conductor 22a may have a plurality of vertical through-holes.

As illustrated in FIG. 1, the connector 23 electrically connects the sub-RF electrode 21 and the jumper 22. As illustrated in FIG. 2, FIGS. 3A and 3B, the connector 23 is a set of a plurality of second conductive wires 23a. The plurality of second conductive wires 23a respectively extend diagonally upward from the plurality of first conductive wires 22b included in the jumper 22, and are respectively connected to the plurality of conductive arc portions 21a included in the sub-RF electrode 21. As described below, a first conductive wire 22b and a corresponding second conductive wire 23a are formed by folding one horizontal conductive wire 26 (FIG. 4). A boundary 24 between the first conductive wire 22b and the second conductive wire 23a is a valley fold line in a plan view. The boundary 24 is located inside the main RF electrode 20 in a plan view. A boundary 25 between a conductive arc portion 21a and a corresponding second conductive wire 23a is a mountain fold line in a plan view. The boundary 25 is provided on the inner edge side of the sub-RF electrode 21. If the width of the first conductive wire 22b and the second conductive wire 23a is too large, it is difficult to fold the material, and if the width is too small, the electrical resistance increases. Thus, in consideration of the trade-off between the width and effect, the width of the first conductive wire 22b and the second conductive wire 23a is preferably set to 5 to 40 mm.

The one-piece structure 30 is obtained by cutting out the sub-RF electrode 21, the jumper 22 and the connector 23 in a contiguous state from a sheet of metal mesh material, and folding the cut-out material. The metal mesh material is e.g., Mo, Nb, W, Ta, carbide of any of these, or a high melting point composite metal containing two or more of these. In order to produce the one-piece structure 30, a sheet of planar metal mesh material is first prepared, and a planar one-piece structure precursor 32 in which the sub-RF electrode 21, the jumper 22 and the connector 23 are contiguous is cut out from the sheet. As illustrated in FIG. 4, the one-piece structure precursor 32 includes: the circular conductor 22a; the plurality of horizontal conductive wires 26 that horizontally extend from the outer edge of the circular conductor 22a and have rotational symmetry; and the plurality of conductive arc portions 21a respectively contiguous to a plurality of horizontal conductive wires 26. Next, each horizontal conductive wire 26 of the one-piece structure precursor 32 is folded into a valley fold at line segment L1 (corresponding to the boundary 24). In addition, each horizontal conductive wire 26 is folded into a mountain fold at line segment L2 (corresponding to the boundary 25) between the conductive arc portion 21a and the corresponding horizontal conductive wire 26. As a result, the plurality of conductive arc portions 21a have a reduced gap between adjacent conductive arc portions 21a, and the sub-RF electrode 21 is formed. Folding each horizontal conductive wire 26 at the line segments L1, L2 forms the first conductive wire 22b and the second conductive wire 23a, and the sub-RF electrode 21 and the jumper 22 have different heights. Consequently, the one-piece structure 30 is obtained.

The tubular shaft 48 is made of the same ceramic material as that for the ceramic plate 12. The tubular shaft 48 is joined to the center of the lower surface 12b of the ceramic plate 12 to support the ceramic plate 12. The outer diameter of the tubular shaft 48 is smaller than the diameter of the ceramic plate 12. The upper end of the tubular shaft 48 is diffusion-bonded to the ceramic plate 12. The main RF electrode rod 40 and the sub-RF electrode rod 41 are disposed in the internal space of the tubular shaft 48.

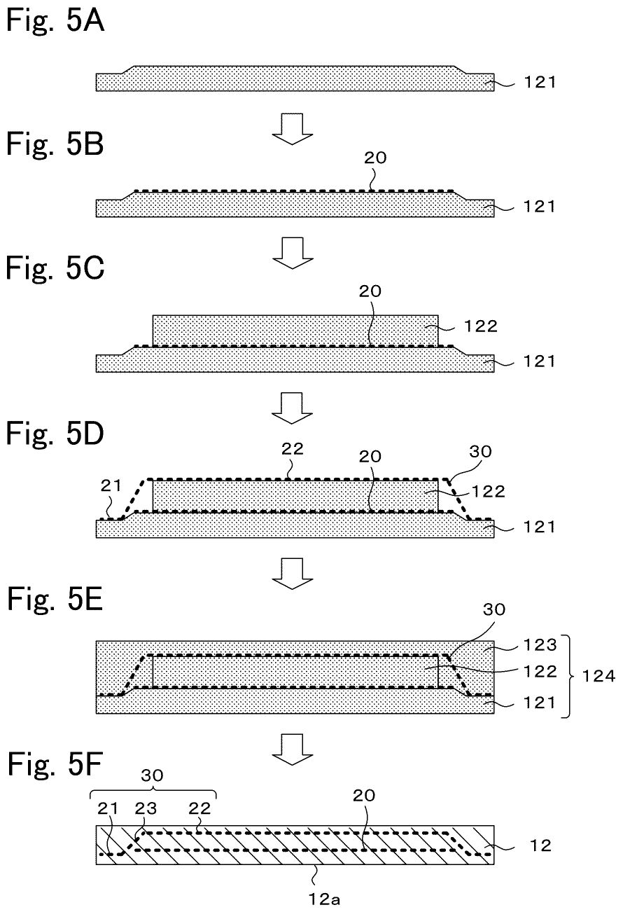

Next, a manufacturing example of the ceramic plate 12 will be described using FIGS. 5A to 5F. FIGS. 5A to 5F show explanatory views illustrating a manufacturing process for the ceramic plate 12. In FIGS. 5A to 5F, the direction of the ceramic plate 12 is vertically opposite to the direction of the ceramic plate 12 in FIG. 1.

First, a first ceramic molded body 121 is produced using ceramic powder having an average particle diameter of several μm to several 10 μm (FIG. 5A). The first ceramic molded body 121 has a shape with a circular truncated cone having a diameter smaller than the diameter of a disk laminated on the disk, and is obtained by compacting, for example, ceramic powder. Subsequently, the circular main RF electrode 20 made of metal mesh is disposed on the uppermost surface (the upper surface of the circular truncated cone) of the first ceramic molded body 121 (FIG. 5B). Subsequently, ceramic powder is placed on the main RF electrode 20, then compacted, thereby forming a disk-shaped second ceramic molded body 122 on the main RF electrode 20 (FIG. 5C). The diameter of the second ceramic molded body 122 is smaller than the diameter of the uppermost surface of the first ceramic molded body 121. In this process, ceramic powder enters mesh openings of the main RF electrode 20. Subsequently, the one-piece structure 30 made of metal mesh is disposed on the second ceramic molded body 122 with the jumper 22 facing upward (FIG. 5D). In this process, the sub-RF electrode 21 comes into contact with the step surface of the first ceramic molded body 121. The diameter of the jumper 22 is slightly larger than the diameter of the second ceramic molded body 122. Subsequently, ceramic powder is placed on the upper surface (exposed surface) of the first ceramic molded body 121 and the upper surface of the second ceramic molded body 122, then is compacted, thereby forming a third ceramic molded body 123 (FIG. 5E). In this process, the ceramic powder enters the mesh openings of the one-piece structure 30 and the mesh openings of the main RF electrode 20. Thus, a disk-shaped ceramic laminated body 124 is obtained, in which the first to third ceramic molded bodies 121 to 123 are integrated. The diameter of the ceramic laminated body 124 is the same as the diameter of the first ceramic molded body 121. The ceramic plate 12 is obtained by hot-press sintering the ceramic laminated body 124 (FIG. 5F). The diameter of the obtained ceramic plate 12 is the same as the diameter of the ceramic laminated body 124, and the thickness of the ceramic plate 12 is approximately half the thickness of the ceramic laminated body 124.

Next, an example of use of the wafer placement table 10 will be described using FIG. 1.

First, the wafer placement table 10 is installed inside the chamber 52. The main RF electrode rod 40 is then connected to the ground via a matching box 50, and the sub-RF electrode rod 41 is connected to the ground via a matching box 51. A shower head 53 is installed in the chamber 52 at a position opposed to the wafer placement table 10. A disk-shaped wafer W is placed on the wafer placement surface 12a of the wafer placement table 10. In this state, the inside of the chamber 52 is set to a predetermined vacuum atmosphere (or a reduced pressure atmosphere), and a plasma is generated in the space above the wafer W while supplying a process gas from the shower head 53. Specifically, a radio-frequency voltage from a radio-frequency (RF) power supply 54 is applied to the shower head 53. Along with this, the impedance of the matching box 50 and the impedance of the matching box 51 are independently controlled. In general, the plasma density in the space above the main RF electrode 20 is likely to be higher than the plasma density in the space above the sub-RF electrode 21. Thus, the impedance of the matching box 50 is set high, and the impedance of the matching box 51 is set low. Consequently, a current is more likely to flow through the sub-RF electrode 21 than through the main RF electrode 20, thus the plasma density in the space above the main RF electrode 20 can be made approximately the same as the plasma density in the space above the sub-RF electrode 21. A CVD film is formed or etching is performed on the wafer W by utilizing the plasma.

Now, the correspondence relationship between the components of the present embodiment and the components of the present invention will be clarified. The ceramic plate 12 of the present embodiment corresponds to a ceramic plate of the present invention, the sub-RF electrode 21 corresponds to a first conductive layer, the jumper 22 corresponds to a second conductive layer, and the connector 23 corresponds to a connector.

In the wafer placement table 10 described above, the sub-RF electrode 21, the jumper 22 and the connector 23 are formed in the seamless one-piece structure 30. Thus, the sub-RF electrode 21 and the connector 23 cannot be disconnected as well as the jumper 22 and the connector 23 cannot be disconnected. Therefore, it is possible to stably ensure the electrical connection between the sub-RF electrode 21 and the jumper 22.

The jumper 22 includes: the horizontal circular conductor 22a provided at a central portion of the ceramic plate 12; and the plurality of first conductive wires 22b that horizontally extend from the outer edge of the circular conductor 22a and have rotational symmetry. The connector 23 is formed by the plurality of second conductive wires 23a that respectively extend diagonally upward from the plurality of first conductive wires 22b. The sub-RF electrode 21 is a ring-shaped set in which the horizontal conductive arc portions 21a respectively contiguous to the plurality of second conductive wires 23a are arranged in a circumferential direction. Therefore, even when the one-piece structure 30 is produced from a relatively hard conductive material (e.g., W and Mo), the one-piece structure 30 can be produced relatively easily. Because the plurality of second conductive wires 23a included in the connector 23 have rotational symmetry, occurrence of variation in the plasma density can be prevented.

In addition, the boundary 24 between the jumper 22 and the connector 23 is located inside the main RF electrode 20 in a plan view. Thus, the angle θ of inclination (FIG. 3B) of the connector 23 can be made small (in other words, made gradual). With the small angle θ of inclination, occurrence of a problem in the vicinity of the connector 23 can be prevented at the time of hot-press sintering in the manufacturing process for the ceramic plate 12.

Furthermore, the boundary 24 between the jumper 22 and the connector 23 is a valley fold line in a plan view, and the boundary between the sub-RF electrode 21 and the connector 23 is a mountain fold line in a plan view. Therefore, the one-piece structure 30 can be manufactured relatively easily.

Also, the wafer placement table 10 includes the tubular shaft 48 joined to the lower surface of the ceramic plate 12, and the main RF electrode rod 40 and the sub-RF electrode rod 41 are disposed in the internal space of the tubular shaft 48. In this wafer placement table 10, the sub-RF electrode rod 41 needs to be disposed in the internal space of the tubular shaft 48, thus application of the present invention has a high significance.

Furthermore, the one-piece structure 30 is made of a metal mesh (conductive mesh). Therefore, when the ceramic plate 12 is manufactured, the ceramic powder is likely to pass through the one-piece structure 30 in a vertical direction, thus the ceramic powder is likely to be distributed over the entirety thereof.

### Second Embodiment

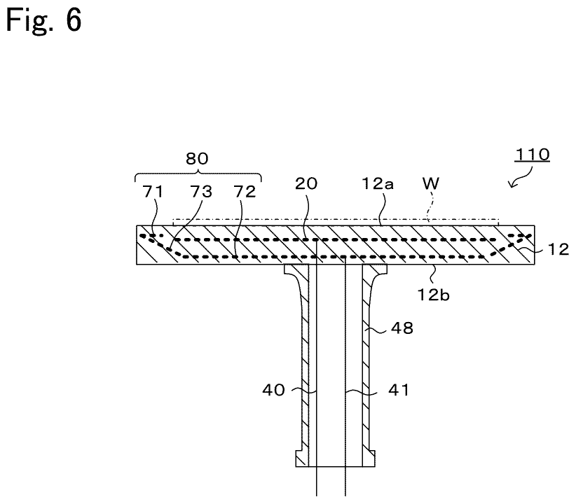

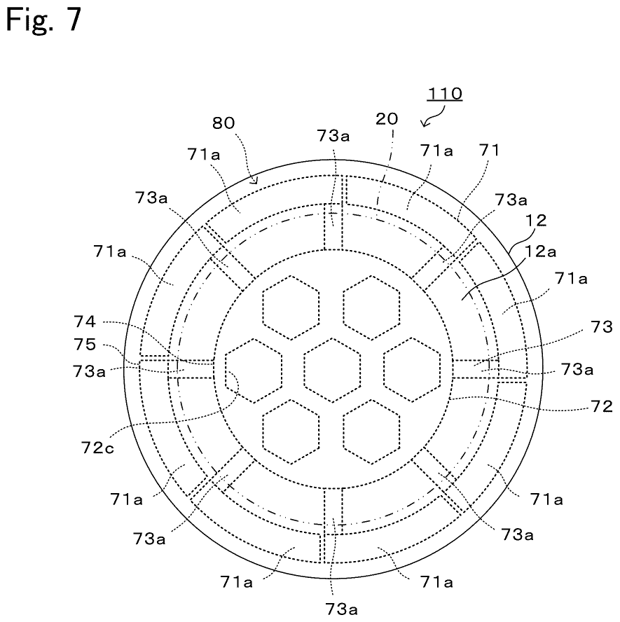

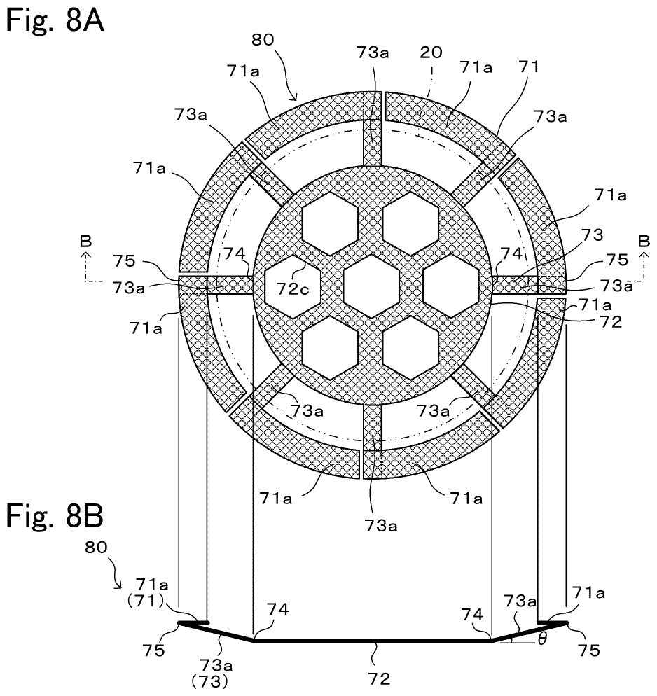

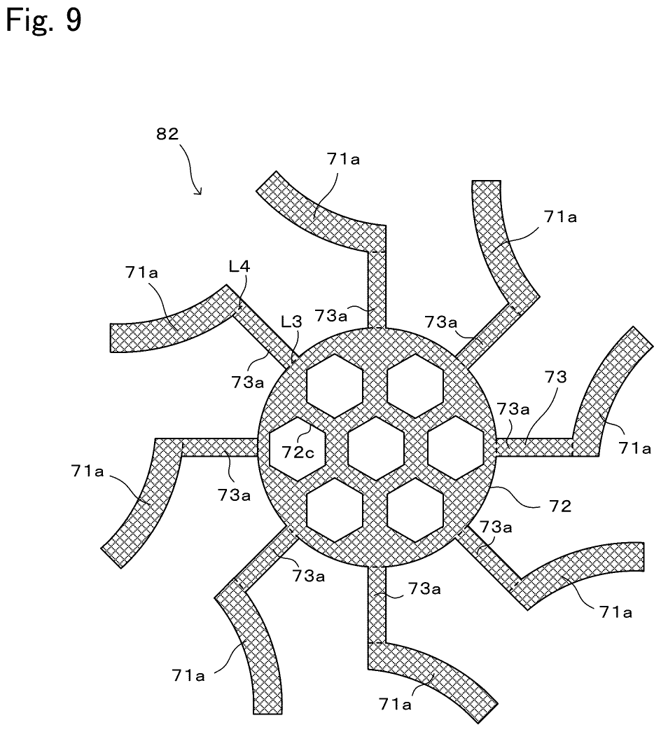

A wafer placement table 110 in a second embodiment is the same as the wafer placement table 10 in the first embodiment except that a one-piece structure 80 is adopted instead of the one-piece structure 30. Thus, the same components as in the first embodiment are labeled with the same symbols, and a description is omitted. FIG. 6 is a vertical cross-sectional view of the wafer placement table 110, FIG. 7 is a plan view of the wafer placement table 110, FIGS. 8A and 8B show explanatory views of one-piece structure 80 (FIG. 8A is a plan view, FIG. 8B is a B-B cross-sectional view), and FIG. 9 is a plan view of one-piece structure precursor 82.

A sub-RF electrode 71, a jumper 72 and a connector 73 are formed in a seamless one-piece structure 80.

As illustrated in FIG. 6, the sub-RF electrode 71 is embedded inside the ceramic plate 12 and above the main RF electrode 20. The sub-RF electrode 71 is disposed on the outer circumferential side of the main RF electrode 20. As illustrated in FIG. 7, FIGS. 8A and 8B, the sub-RF electrode 71 is a ring-shaped set in which a plurality of horizontal conductive arc portions 71a are arranged in a circumferential direction. Adjacent conductive arc portions 71a of the sub-RF electrode 71 are disposed with a slight gap. However, adjacent conductive arc portions 71a may be disposed so as to overlap with each other. As illustrated in FIG. 7, the inner diameter of the ring-shaped sub-RF electrode 71 is greater than the outer diameter of the main RF electrode 20, and the outer diameter of the ring-shaped sub-RF electrode 71 is less than the diameter of the ceramic plate 12. The width of the sub-RF electrode 71 is preferably 5 to 40 mm.

As illustrated in FIG. 6, the jumper 72 is embedded inside the ceramic plate 12 and below the main RF electrode 20 and the sub-RF electrode 71. The jumper 72 is electrically connected to the sub-RF electrode rod 41 which is inserted in the lower surface 12b of the ceramic plate 12. The distance between the jumper 72 and the sub-RF electrode 71 in the height direction is preferably 2 to 20 mm. As illustrated in FIG. 7, FIGS. 8A and 8B, the jumper 72 is a horizontal circular conductor provided at a central portion of the ceramic plate 12 (FIG. 7). The jumper 72 has a plurality of vertical through-holes 72c. Thus, the area of the jumper 72 is smaller than in the case where the jumper 72 does not have holes 72c.

As illustrated in FIG. 6, the connector 73 electrically connects the sub-RF electrode 71 and the jumper 72. As illustrated in FIG. 7, FIGS. 8A and 8B, the connector 73 is a set of a plurality of conductive wires 73a. The plurality of conductive wires 73a extend diagonally upward from the outer edge of the jumper 72 and have rotational symmetry, and are respectively connected to the plurality of conductive arc portions 71a included in the sub-RF electrode 71. A boundary 74 between the jumper 72 and each conductive wire 73a is a valley fold line in a plan view. The boundary 74 is located inside the main RF electrode 20 in a plan view. A boundary 75 between a conductive arc portion 71a and a corresponding conductive wire 73a is a valley fold line in a plan view. The boundary 75 is provided on the outer edge side of the sub-RF electrode 71. If the width of the conductive wire 73a is too large, it is difficult to fold the material, and if the width is too small, the electrical resistance increases. Thus, in consideration of the trade-off between the width and effect, the width of the conductive wire 73a is preferably set to 5 to 40 mm.

The one-piece structure 80 is obtained by cutting out the sub-RF electrode 71, the jumper 72 and the connector 73 in a contiguous state from a sheet of metal mesh material, and folding the cut-out material. The metal mesh material is e.g., Mo, Nb, W, Ta, carbide of any of these, or a high melting point composite metal containing two or more of these. In order to produce the one-piece structure 80, a sheet of planar metal mesh material is first prepared, and a planar one-piece structure precursor 82 in which the sub-RF electrode 71, the jumper 72 and the connector 73 are contiguous is cut out from the sheet. As illustrated in FIG. 9, the one-piece structure precursor 82 includes: the jumper 72 which is a circular conductor; the plurality of conductive wires 73a that horizontally extend from the outer edge of the jumper 72 and have rotational symmetry; and the plurality of conductive arc portions 71a respectively contiguous to the plurality of conductive wires 73a. Next, each conductive wire 73a of the one-piece structure precursor 82 is folded into a valley fold at line segment L3 (corresponding to the boundary 74). In addition, the conductive wire 73a is folded into a valley fold at line segment L4 (corresponding to the boundary 75) between the conductive arc portion 71a and the conductive wire 73a. As a result, the plurality of conductive arc portions 71a are vertically inverted to reduce the gap between adjacent conductive arc portions 71a, and the sub-RF electrode 71 is formed. Folding both ends of the conductive wire 73a at the line segments L3, L4 forms the sub-RF electrode 71 and the jumper 72 with different heights. Consequently, the one-piece structure 80 is obtained.

The manufacturing process for the ceramic plate 12 in the second embodiment is the same as the manufacturing process for the ceramic plate 12 in the first embodiment except that the one-piece structure 80 is used instead of the one-piece structure 30.

In the wafer placement table 110 described above, the sub-RF electrode 71, the jumper 72 and the connector 73 are formed in the seamless one-piece structure 80. Thus, the sub-RF electrode 71 and the connector 73 cannot be disconnected as well as the jumper 72 and the connector 73 cannot be disconnected. Therefore, it is possible to stably ensure the electrical connection between the sub-RF electrode 71 and the jumper 72.

The jumper 72 is a horizontal circular conductor provided at a central portion of the ceramic plate 12. The connector 73 is formed by the plurality of conductive wires 73a that extend diagonally upward from the outer edge of the jumper 72 as a circular conductor and have rotational symmetry. The sub-RF electrode 71 is a ring-shaped set in which the horizontal conductive arc portions 71a respectively contiguous to the plurality of conductive wires 73a are arranged in a circumferential direction. Therefore, even when the one-piece structure 80 is produced from a relatively hard conductive material (e.g., W and Mo), the one-piece structure 80 can be produced relatively easily. Because the plurality of conductive wires 73a included in the connector 73 have rotational symmetry, occurrence of variation in the plasma density can be prevented.

In addition, the boundary 74 between the jumper 72 and the connector 73 is located inside the main RF electrode 20 in a plan view. Thus, the angle θ of inclination (FIG. 8B) of the connector 73 can be made small (in other words, made gradual). With the small angle θ of inclination, occurrence of a problem in the vicinity of the connector 73 can be prevented at the time of hot-press sintering in the manufacturing process for the ceramic plate 12.

Furthermore, the boundary 74 between the jumper 72 and the connector 73 is a valley fold line in a plan view, and the boundary between the sub-RF electrode 71 and the connector 73 is also a valley fold line in a plan view. Therefore, as compared to the first embodiment, the angle θ of inclination of the connector 73 can be further reduced, and the distance between the connector 73 and the main RF electrode 20 can be sufficiently secured.

Also, the wafer placement table 110 includes the tubular shaft 48 joined to the lower surface of the ceramic plate 12, and the main RF electrode rod 40 and the sub-RF electrode rod 41 are disposed in the internal space of the tubular shaft 48. In this wafer placement table 110, the sub-RF electrode rod 41 needs to be disposed in the internal space of the tubular shaft 48, thus application of the present invention has a high significance.

Furthermore, the one-piece structure 80 is made of a metal mesh (conductive mesh). Therefore, when the ceramic plate 12 is manufactured, the ceramic powder is likely to pass through the one-piece structure 80 in a vertical direction, thus the ceramic powder is likely to be distributed over the entirety thereof.

### Other Embodiments

Note that the present invention is not limited to the above-described embodiment at all, and it is needless to say that the present invention can be carried out in various forms as long as the forms belong to the technical scope of the present invention.

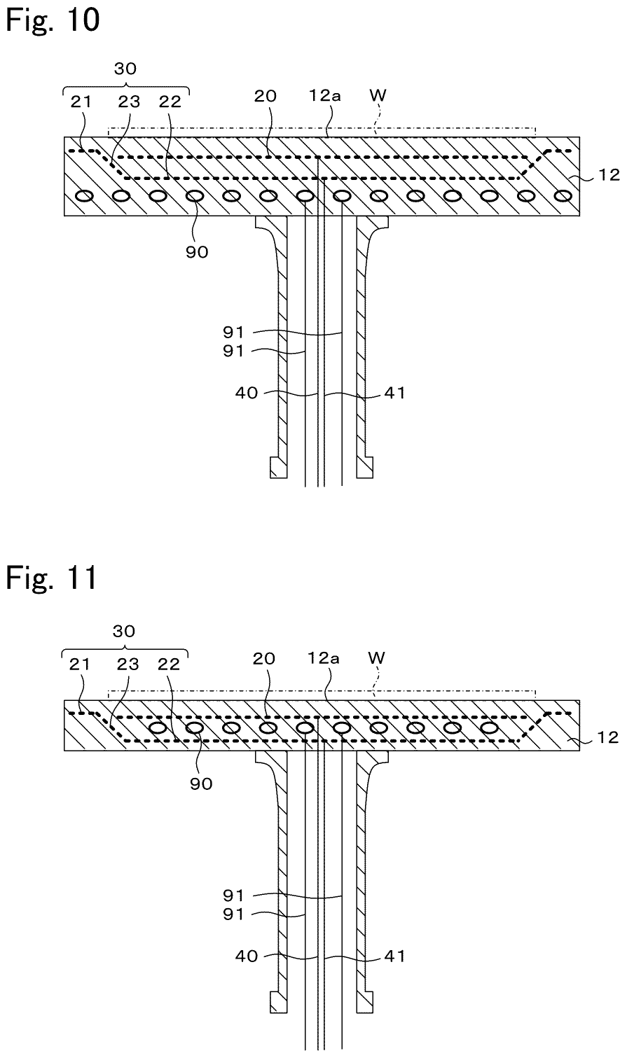

For example, in the first embodiment described above, as illustrated in FIG. 10 and FIG. 11, resistance heating element (heater electrode) 90 may be embedded inside the ceramic plate 12. The resistance heating element 90 is embedded below the main RF electrode 20. FIG. 10 shows an example in which the resistance heating element 90 is embedded below the main RF electrode 20 and the jumper 22, whereas FIG. 11 shows an example in which the resistance heating element 90 is embedded below the main RF electrode 20 and above the jumper 22. In FIG. 10 and FIG. 11, the same components as in the first embodiment are labeled with the same symbols. The resistance heating element 90 is provided from one of a pair of terminals to the other of the pair of terminals through wiring on the entire surface of the wafer placement surface 12a in a plan view. Power supply rods 91 are respectively electrically connected to the pair of terminals of the resistance heating element 90. Each power supply rod 91 is connected to a heater power supply which is not illustrated. Note that in FIG. 11, the power supply rod 91 is provided so as not to be in contact with the jumper 22. The resistance heating element 90 is supplied with electric power from the heater power supply through the power supply rod 91, thereby generating heat to heat the wafer W. The shape of the resistance heating element 90 is, for example, coil and ribbon. This also applies to the second embodiment.

In the first embodiment described above, eight first conductive wires 22b are provided from the outer edge of the circular conductor 22a with equal angle interval (45° interval) so as to have rotational symmetry, but the present invention is not limited to this. For example, n first conductive wires may be provided from the outer edge of the circular conductor with equal angle interval ((360/n)° interval), where n is an integer greater than or equal to 2. This also applies to the second embodiment.

The first embodiment described above shows an example in which the sub-RF electrode 21 is provided above the main RF electrode 20, but the present invention is not limited to this. For example, the sub-RF electrode 21 may be provided below the main RF electrode 20, or the sub-RF electrode 71 may be provided at the same height as that of the main RF electrode 20. This also applies to the second embodiment.

International Application No. PCT/JP2023/046069,filed on Dec. 22, 2023, is incorporated herein by reference in its entirety.

What is claimed is:

1. A wafer placement table comprising:
a first conductive layer; a second conductive layer different in height from the first conductive layer; and a connector that electrically connect the first conductive layer and the second conductive layer, inside a ceramic plate having a wafer placement surface on its upper surface,
wherein the first conductive layer, the second conductive layer and the connector are formed in a seamless one-piece structure.

2. The wafer placement table according to claim 1, further comprising:
a main RF electrode provided inside the ceramic plate;
a sub-RF electrode as the first conductive layer provided on an outer circumferential side of the main RF electrode;
a jumper as the second conductive layer provided below the sub-RF electrode;
a main RF electrode rod electrically connected to the main RF electrode; and
a sub-RF electrode rod electrically connected to the jumper.

3. The wafer placement table according to claim 2,
wherein the jumper includes a horizontal conductor provided at a central portion of the ceramic plate; and a plurality of first conductive wires that horizontally extend from an outer edge of the conductor and have rotational symmetry,
the connector is formed by a plurality of second conductive wires that respectively extend diagonally upward from the plurality of first conductive wires, and
the sub-RF electrode is a ring-shaped set in which horizontal conductive arc portions respectively contiguous to the plurality of second conductive wires are arranged in a circumferential direction.

4. The wafer placement table according to claim 2,
wherein the jumper is a horizontal conductor provided at a central portion of the ceramic plate,
the connector is formed by a plurality of conductive wires that extend diagonally upward from an outer edge of the conductor and have rotational symmetry, and
the sub-RF electrode is a ring-shaped set in which horizontal conductive arc portions respectively contiguous to the plurality of conductive wires are arranged in a circumferential direction.

5. The wafer placement table according to claim 2,
wherein a boundary between the jumper and the connector is located inside the main RF electrode in a plan view.

6. The wafer placement table according to claim 2,
wherein a boundary between the jumper and the connector is a valley fold line in a plan view, and
a boundary between the sub-RF electrode and the connector is a mountain fold line in a plan view.

7. The wafer placement table according to claim 2,
wherein a boundary between the jumper and the connector is a valley fold line in a plan view, and
a boundary between the sub-RF electrode and the connector is a valley fold line in a plan view.

8. The wafer placement table according to claim 2, further comprising
a tubular shaft connected to a lower surface of the ceramic plate,
wherein the main RF electrode rod and the sub-RF electrode rod are disposed in an internal space of the tubular shaft.

9. The wafer placement table according to claim 1,
wherein the one-piece structure is made of a conductive mesh.

10. The wafer placement table according to claim 3,
wherein the conductor of the jumper has a vertical through-hole.
